(19) United States
(12) Patent Application Publication
(10) Pub. No.: US 2025/0309892 A1
(43) Pub. Date: Oct. 2, 2025

(54) SYSTEMS AND METHODS FOR POWER FIELD EFFECT TRANSISTOR CONTROL

(71) Applicant: Advanced Micro Devices, Inc., Santa Clara, CA (US)

(72) Inventors: Stephen Dussinger, Fort Collins, CO (US); Jeffrey Lucas, Fort Collins, CO (US)

(73) Assignee: Advanced Micro Devices, Inc., Santa Clara, CA (US)

(21) Appl. No.: 18/618,875

(22) Filed: Mar. 27, 2024

(51) Int. Cl. H03K 17/687; H01L 23/31; H01L 23/48; H01L 23/498; H01L 25/065

(52) U.S. Cl. CPC H03K 17/6871; H01L 23/3107; H01L 23/481; H01L 23/49838; H01L 25/0657; H01L 2225/06541

(57) ABSTRACT

A method for power field effect transistor control can include configuring one or more input power networks to supply power to a plurality of field effect transistors. The method can also include configuring one or more gated output power networks to receive gated power from the plurality of field effect transistors. The method can further include configuring the plurality of field effect transistors to receive a pulse width modulated control signal and to gate the supplied power in response to the pulse width modulated control signal. Various other methods and systems are also disclosed.

### BACKGROUND

An integrated circuit (e.g., an IC, a chip, or a microchip) is a set of electronic circuits on one small flat piece of semiconductor material, usually silicon. Large numbers of miniaturized transistors and other electronic components are integrated together on the chip. Chips containing integrated circuits can be implemented in a semiconductor device.

A semiconductor device is an electronic component that relies on the electronic properties of a semiconductor material (e.g., silicon, germanium, gallium arsenide, and/or organic semiconductors) for its function. Its conductivity lies between conductors and insulators. Semiconductor devices can be implemented in semiconductor device packages.

A semiconductor device package is a metal, plastic, glass, or ceramic casing containing one or more discrete semiconductor devices or integrated circuits. Individual components can be fabricated on semiconductor wafers (e.g., silicon) before being diced into die, tested, and packaged. The package provides a means for connecting it to the external environment, such as printed circuit board, via leads such as lands, balls, or pins; and protection against threats such as mechanical impact, chemical contamination, and light exposure. Additionally, it helps dissipate heat produced by the device, with or without the aid of a heat spreader. Semiconductor device packages can include a package substrate.

A package substrate is a piece of insulator (e.g., a flat piece) with internal conducting pathways (e.g., planes, wires, planes patterned into wires, etc.) onto which an integrated circuit can be mounted. For example, input and output pins of an integrated circuit can be individually connected (e.g., by wire bonding or bump bonding) to metal leads on the substrate. These leads can connect the integrated circuit to other parts of the package. Package substrates can contain field effect transistors.

A field effect transistor is a device that can control current flow. For example, a field effect transistor can correspond to a power field effect transistor corresponding to one or more gates, one or more field effect transistors (FETs), one or more power channel (p-channel) FETs (PFETS), and/or one or more metal-oxide-semiconductor (MOS) FETs (MOSFETs). In this context, a conductance configurable field effect transistor can vary conductance in response to an enable signal received on an input (e.g., transistor leg) of the device. In some implementations, a field effect transistor can include a collection of such devices. For example, a PFET can correspond to a collection (e.g., an array) of individual pFETs.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a flow diagram of an example method for power field effect transistor control.

FIG. 2 is a block diagram illustrating an example device for power field effect transistor control.

FIG. 3 is a block diagram illustrating an example device for power field effect transistor control.

FIG. 4 is a block diagram illustrating an example die including an example device for power field effect transistor control.

FIG. 5 is a block diagram illustrating an example semiconductor device package including an example device for power field effect transistor control.

FIG. 6 is a block diagram illustrating an example semiconductor device package implementing power field effect transistor control.

FIG. 7 is a block diagram illustrating an example semiconductor device package implementing control of power field effect transistors located in an example package substrate.

FIG. 8 is a block diagram illustrating an example semiconductor device package including an example device for control of power field effect transistors located in an example package substrate.

FIG. 9 is a block diagram illustrating example semiconductor device packages including example devices for control of power field effect transistors located in example package substrates.

FIG. 10 is a block diagram illustrating an example semiconductor device package implementing control of power field effect transistors located in one or more die.

FIG. 11 is a block diagram illustrating an example semiconductor device package including an example device for control of power field effect transistors located in one or more die.

FIG. 12 is a block diagram illustrating an example semiconductor device package including an example device for control of power field effect transistors located in one or more die.

FIG. 13 is a block diagram illustrating an example semiconductor device package including an example device for control of power field effect transistors located in one or more die.

FIG. 14 is a block diagram illustrating an example semiconductor device package implementing control of power field effect transistors located in one or more 3D stacked die.

FIG. 15 is a block diagram illustrating an example semiconductor device package including an example device for control of power field effect transistors located in one or more 3D stacked die.

FIG. 16 is a block diagram illustrating an example semiconductor device package including an example device for control of power field effect transistors located in one or more 3D stacked die.

FIG. 17 is a block diagram illustrating an example semiconductor device package including an example device for control of power field effect transistors located in one or more 3D stacked die.

FIG. 18 is a block diagram illustrating an example semiconductor device package including an example device for control of power field effect transistors located in one or more 3D stacked die.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for power field effect transistor control. For example, by configuring one or more input power networks to supply power to a plurality of field effect transistors, configuring one or more gated output power networks to receive gated power from the plurality of field effect transistors, and configuring the plurality of field effect transistors to receive a pulse width modulated control signal and to gate the supplied power in response to the pulse width modulated control signal, numerous benefits can be achieved.

Benefits achieved by the disclosed systems and methods can arise, at least in part, by avoiding breaking up field effect transistors into different strength FETs and/or using multiple control lines to control different groups of field effect transistors to achieve different conductances. Instead, the disclosed systems and methods can ramp power supplies through power field effect transistor FETs and use a Pulse-Width-Modulation (PWM) scheme to control all power field effect transistors with a common control signal. Such implementations of the disclosed systems and methods can simplify the control of field effect transistor conductance by avoiding use of different control lines to different field effect transistor macros and reducing the number of signals needed for control to one. Such implementations can also simplify field effect transistor macro design because only one type of macro is needed with only a single field effect transistor macro FET strength required. This benefit can arise when the overall field effect transistor conductance is modulated by the PWM pulse duty-cycle, instead of by enabling different amounts of field effect transistor macros or different strength FETs inside the field effect transistor macros. Additionally, since all of the FETs can be substantially identical (e.g., in terms of field effect transistor strength and aging effect, nearly identical within a statistical distribution having a small sigma, etc.) and can be turned on and off simultaneously, substantially uniform wear (e.g., wear leveling) can be achieved.

Certain implementations of the disclosed systems and methods can achieve conductance changes through PWM shaping of the common control signal, instead of through quantizing FET strengths inside the power field effect transistor macros and/or more complex, multi-bit control schemes. Thus, these implementations can aid FET overheating/degradation prevention by providing periodic off-time to allow the FETs to recover from thermal and current-flow stresses as the gated output supply value is ramped up or down in voltage level. Additionally or alternatively, by using a sufficiently short PWM control signal period, implementations of the disclosed systems and methods can achieve improved voltage ramp profile control, provided that the characteristic response time of the gated supply network (e.g., gated output power network) is significantly longer than the PWM period (e.g., a response time approximately three orders of magnitude greater than a PWM period, a PWM period on the order of nanoseconds for a characteristic response time on the order of microseconds, a response time more than two orders of magnitude greater than a PWM period, etc.). Further, these implementations can also use one control signal for all field effect transistor macros, thus causing all FETs of all field effect transistor macros to experience the same stress profile over time, which can achieve a uniform wear/degradation profile across all power field effect transistor FETs as time-in-use accumulates. Some of these implementations can increase (e.g., maximize) service life of the power field effect transistors by progressively modulating the effective field effect transistor conductance over time in order to achieve improved voltage ramp profile control and avoid overheating of field effect transistor FETs, thus resulting in even degradation/wear across all the field effect transistor FETs. Finally, the power field effect transistor conductance profile can be continuous, and its quantization can be limited only by the resolution of the control signal's duty cycle.

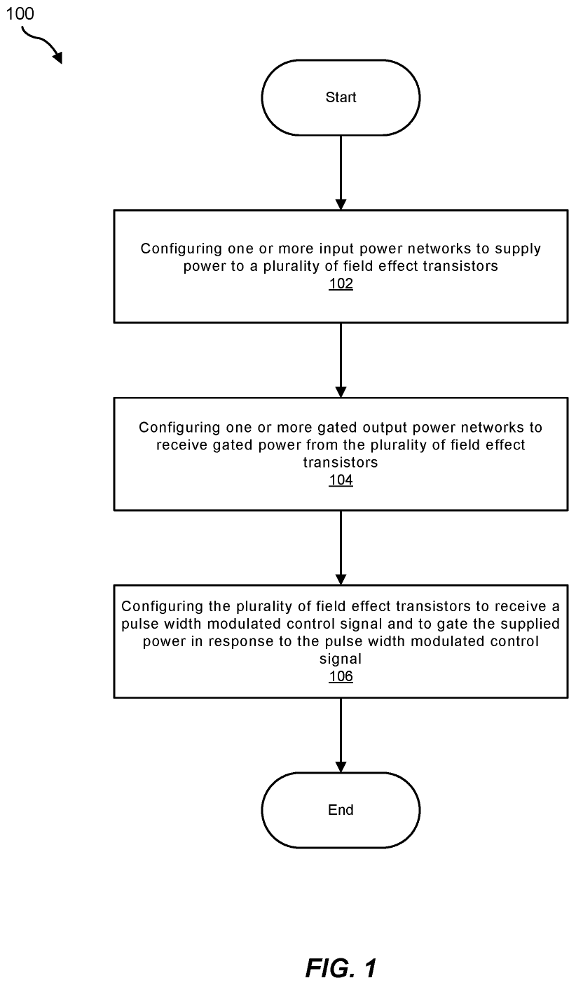

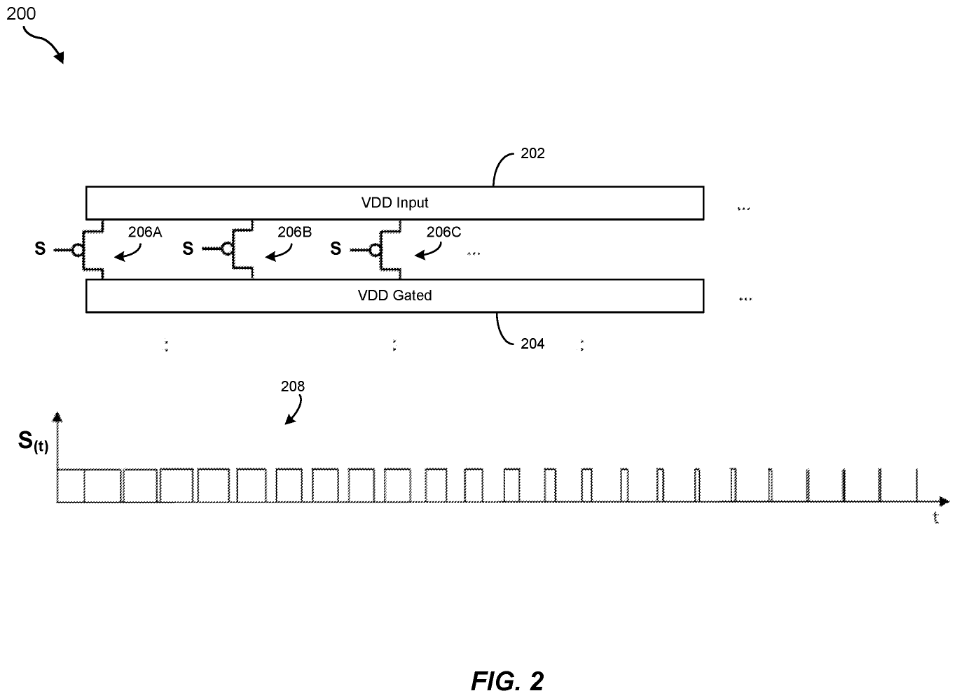

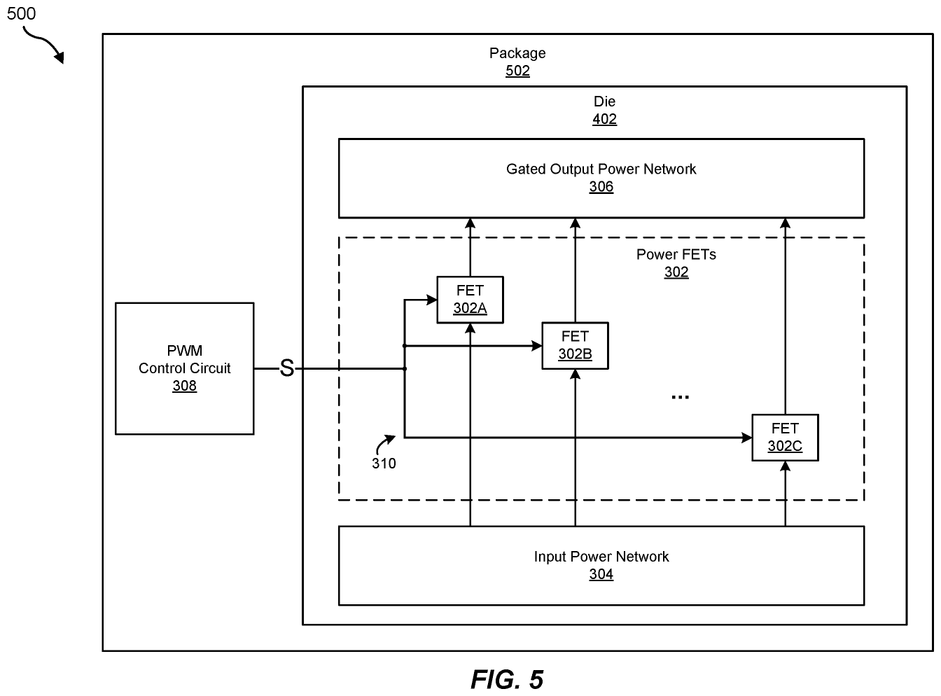

The following will provide, with reference to FIG. 1, detailed descriptions of example methods for power field effect transistor control. Detailed descriptions of example devices implementing power field effect transistor control will also be provided in connection with FIGS. 2-4. In addition, detailed descriptions of example semiconductor device packages implementing power field effect transistor control will be provided in connection with FIGS. 5-18.

In one example, a device can include one or more input power networks, one or more gated output power networks, and a plurality of field effect transistors configured to receive power supplied by the one or more input power networks and a pulse width modulated control signal, wherein the plurality of field effect transistors is configured to gate the supplied power in response to the pulse width modulated control signal and convey the gated power to the one or more gated output power networks.

Another example can be the previously described example device, wherein field effect transistor strengths of all field effect transistors of the plurality of field effect transistors are identical.

Another example can be any of the previously described example devices, wherein the pulse width modulated control signal corresponds to a common control signal received by all field effect transistors of the plurality of field effect transistors.

Another example can be any of the previously described example devices, further including a pulse width modulation control circuit supplying the pulse width modulated control signal to the plurality of field effect transistors, wherein the pulse width modulation control circuit is configured to cause the pulse width modulated control signal to exhibit a period having a duration less than a characteristic response time of the one or more gated output power networks and a configurable duty cycle.

Another example can be any of the previously described example devices, wherein the device corresponds to one or more semiconductor layers of a semiconductor device.

Another example can be any of the previously described example devices, wherein the one or more semiconductor layers correspond to one or more die of the semiconductor device.

Another example can be any of the previously described example devices, wherein the pulse width modulation control circuit is located on the one or more die, on a semiconductor device package including the semiconductor device, and/or off of the semiconductor device package including the semiconductor device.

Another example can be any of the previously described example devices, wherein at least one of the one or more semiconductor layers corresponds to a package substrate of a semiconductor device package.

Another example can be any of the previously described example devices, wherein the pulse width modulation control circuit is located on the package substrate, on the semiconductor device package including the package substrate, and/or off of the semiconductor device package including the package substrate.

In one example, a semiconductor device package can include a package substrate, one or more die located on the package substrate, and a plurality of field effect transistors configured to receive power supplied by one or more input power networks of the semiconductor device package and a pulse width modulated control signal, wherein the plurality of field effect transistors is configured to gate the supplied power in response to the pulse width modulated control signal and convey the gated power to one or more gated output power networks of the semiconductor device package.

Another example can be the previously described example semiconductor device package, wherein the plurality of field effect transistors is located in the package substrate and/or the one or more die.

Another example can be any of the previously described example semiconductor device packages, wherein field effect transistor strengths of all field effect transistors of the plurality of field effect transistors are identical.

Another example can be any of the previously described example semiconductor device packages, wherein the pulse width modulated control signal corresponds to a common control signal received by all field effect transistors of the plurality of field effect transistors.

Another example can be any of the previously described example semiconductor device packages, further including a pulse width modulation control circuit supplying the pulse width modulated control signal to the plurality of field effect transistors.

Another example can be any of the previously described example semiconductor device packages, wherein the pulse width modulation control circuit is configured to cause the pulse width modulated control signal to exhibit a period having a duration less than a characteristic response time of the one or more gated output power networks and a configurable duty cycle.

Another example can be any of the previously described example semiconductor device packages, wherein the pulse width modulation control circuit is located on the one or more die, on the package substrate, on the semiconductor device package including the package substrate, or off of the semiconductor device package including the package substrate.

In an example, a method can include configuring one or more input power networks to supply power to a plurality of field effect transistors, configuring one or more gated output power networks to receive gated power from the plurality of field effect transistors, and configuring the plurality of field effect transistors to receive a pulse width modulated control signal and to gate the supplied power in response to the pulse width modulated control signal.

Another example can be the previously described example method, wherein field effect transistor strengths of all field effect transistors of the plurality of field effect transistors are identical.

Another example can be any of the previously described example methods, wherein the pulse width modulated control signal corresponds to a common control signal received by all field effect transistors of the plurality of field effect transistors.

Another example can be the previously described example method, further including configuring a pulse width modulation control circuit to supply the pulse width modulated control signal to the plurality of field effect transistors, wherein the pulse width modulation control circuit is configured to cause the pulse width modulated control signal to exhibit a period having a duration less than a characteristic response time of the one or more gated output power networks and a configurable duty cycle.

FIG. 1 is a flow diagram of an example method 100 for power field effect transistor control. As illustrated in FIG. 1, at step 102, method 100 can configure one or more input power networks. For example, method 100 can, at step 102, configure one or more input power networks to supply power to a plurality of field effect transistors.

The term “power,” as used herein, can generally refer to a rate of electrical energy transfer by an electric circuit per unit of time. For example, and without limitation, power can be denoted by P and measured using an SI unit of power corresponding to one watt or one joule per second. Electric power can commonly be supplied by electric batteries and produced by electric generators.

The term “input power network,” as used herein, can generally refer to one or more metal layers that supply ungated power. For example, and without limitation, an input power network can include one or more metal layers supplying a voltage drain to drain (VDD) in a semiconductor device package substrate and/or in a die of a semiconductor device. In this context, a power network can include a plane, a wire, and/or any other metallization shape.

The term “field effect transistor,” as used herein, can generally refer to a device that can control current flow. For example, and without limitation, field effect transistor can refer to a power field effect transistor corresponding to one or more gates, one or moreheaders, one or more power channel (p-channel) FETs (PFETS), and/or one or more metal-oxide-semiconductor (MOS) FETs (MOSFETs). In this context, a conductance configurable field effect transistor can vary conductance in response to an enable signal received on an input (e.g., transistor leg) of the device. In some implementations, a field effect transistor can include a collection of such devices. For example, and without limitation, a PFET can correspond to a collection (e.g., an array) of FETs. In this context, a plurality of field effect transistors can include two or more FETS of a power FET, two or more power FETS, etc.

The term “p-channel,” as used herein, can generally refer to using hole flow as a charge carrier. For example, and without limitation, a p-channel MOSFET can correspond to a type of MOSFET in which the channel is composed with a majority of charge carriers as holes (e.g., as opposed to using electron flow as a charge carrier as with n-channel MOSFETS). Once a p-channel MOSFET is activated, then the majority of charge carriers like holes can move throughout the channel.

The term “metal oxide semiconductor,” as used herein, can generally refer to a three-layer sandwich of a metal, an insulator (e.g., an oxide of a substrate), and a semiconductor substrate, used in integrated circuits. For example, and without limitation, a MOSFET can correspond to a type of FET often fabricated by controlled oxidation of silicon and having an insulated gate, the voltage of which determines the conductivity of the device.

The systems described herein can perform step 102 in a variety of ways. For example, method 100 can, at step 102, locate the one or more input power networks within a die of a semiconductor device of a semiconductor device package. Alternatively or additionally, method 100 can, at step 102, locate the one or more input power networks within a package substrate of a semiconductor device package. Alternatively or additionally, method 100 can, at step 102, connect the one or more input power networks to the plurality of field effect transistors using one or more metal layers, one or more through silicon vias, one or more wires, and/or one or more bumps.

The term “die,” as used herein, can generally refer to a small block of semiconducting material on which a given functional circuit is fabricated. For example, and without limitation, integrated circuits can be produced in large batches on a single wafer of electronic-grade silicon (EGS) or other semiconductor (e.g., GaAs) through processes such as photolithography. The wafer can be cut (diced) into many pieces, each containing one copy of the circuit. Each of these pieces can be called a die.

The term “package substrate,” as used herein, can generally refer to a (e.g., flat) piece of insulator on which an integrated circuit can be mounted. For example, and without limitation, input and output pins of an integrated circuit can be individually connected (e.g., by wire bonding or bump bonding) to metal leads on the substrate. These leads can connect the integrated circuit to other parts of the package, to a circuit board on which the package is mounted, etc.

The term “through silicon via,” as used herein, can generally refer to metalized holes or pillars providing a vertical interconnect between individual, stacked wafers and/or individual, stacked dies to form customized, multilayer, multifunctional devices. For example, and without limitation, through silicon vias can completely pass through a silicon die or wafer to allow for stacking of silicon die.

The term “metal layer,” as used herein, can generally refer to wiring in and/or on a wafer and/or chip that interconnects individual devices (e.g., transistors, capacitors, resistors, etc.) of an integrated circuit. For example, and without limitation, a metal layer can include copper and/or aluminum.

At step 104, method 100 can configure one or more gated output power networks. For example, method 100 can, at step 104, configure one or more gated output power networks to receive gated power from the plurality of field effect transistors.

The term “gate,” as used herein, can generally refer to a device that can switch a channel on or off or the act of switching a channel on or off. For example, and without limitation, a PFET can correspond to a gate that is high conductance in response to a low enable signal (e.g., a zero) and low-conductance in response to a high enable signal (e.g., a one). In this context, power can be gated by such a device, resulting in gated power that has been controlled by the device.

The term “control,” as used herein, can generally refer to gating and/or regulating the output of a supply voltage. For example, and without limitation, control can correspond to enabling and/or disabling one or more field effect transistors to gate or ungate a power channel (e.g., through silicon via, wire, metal layer, etc.).

The term “gated output power network,” as used herein, can generally refer to one or more metal layers that supply gated power. For example, and without limitation, a gated output power network can include one or more metal layers supplying a gated VDD in a semiconductor device package substrate and/or in a die of a semiconductor device. In this context, a gated output power network can be switched on only part of the time and/or can be connected to an ungated supply through a variable-conduction pathway (e.g., pFETs).

The systems described herein can perform step 104 in a variety of ways. For example, method 100 can, at step 104, locate the one or more gated output power networks within a die of a semiconductor device of a semiconductor device package. In some of these implementations, method 100 can, at step 104, locate the one or more gated output power networks within a same die in which the one or more input power networks are located. Alternatively or additionally, method 100 can, at step 102, locate the one or more gated output power networks within a different die than one in which the one or more input power networks are located. Alternatively or additionally, method 100 can, at step 102, locate the one or more gated output power networks within a die of a semiconductor device situated on a package substrate in which the one or more input power networks are located. Alternatively or additionally, method 100 can, at step 102, locate the one or more gated output power networks within a package substrate of a semiconductor device package. In some of these implementations, method 100 can, at step 104, locate the one or more gated output power networks within a same package substrate in which the one or more input power networks are located. Alternatively or additionally, method 100 can, at step 102, connect the one or more gated output power networks to the plurality of field effect transistors using one or more metal layers, one or more through silicon vias, one or more wires, and/or one or more bumps.

At step 106, method 100 can configure the plurality of field effect transistors. For example, method 100 can, at step 106, configure the plurality of field effect transistors to receive a pulse width modulated control signal and to gate the supplied power in response to the pulse width modulated control signal.

The term “pulse width modulation (PWM),” as used herein, can generally refer to the act of controlling the average power or amplitude delivered by an electrical signal. For example, and without limitation, the average value of voltage (and current) fed to a load can be controlled by repeatedly pulsing off and on a load's power supply using a configurable duty cycle, and typically with a pulse period shorter than a response time of the load (e.g., a response time approximately three orders of magnitude greater than a PWM period, a PWM period on the order of nanoseconds for a characteristic response time on the order of microseconds, a response time more than two orders of magnitude greater than a PWM period, etc.). In this context, the total power supplied to the load can increase with the duty cycle of the PWM control signal.

The term “control signal,” as used herein, can generally refer to a pulse or frequency of energy (e.g., electricity, light, etc.) that represents a control command as it travels over a communication medium (e.g., wire, metal layer, through silicon via, bump, etc.). For example, and without limitation, a control signal can correspond to an enable signal on a communication medium connected to an input (e.g., transistor leg) of a power field effect transistor.

The term “enable,” as used herein, can generally refer to turning on a device. For example, and without limitation, a field effect transistor can be enabled by an enable signal (e.g., a logical one or a logical zero) provided to an input (e.g., a transistor leg) of the field effect transistor.

The term “pulse width modulated control signal,” as used herein, can generally refer to an enable signal switched between 0 and 100% at a rate that controls gating applied to power by the plurality of power field effect transistors. For example, and without limitation, the pulse width modulated control signal can correspond to an enable signal switched between 0 and 100% at a rate faster than a characteristic response time of the gated output power network (e.g., a response time approximately three orders of magnitude greater than a PWM period, a PWM period on the order of nanoseconds for a characteristic response time on the order of microseconds, a response time more than two orders of magnitude greater than a PWM period, etc.). This pulse width modulation of the enable signal can control the gating performed by the plurality of power field effect transistors in a manner that regulates the gated output power of the one or more gated output power networks.

The systems described herein can perform step 106 in a variety of ways. For example, method 100 can, at step 106, configure the plurality of field effect transistors in which field effect transistor strengths of all field effect transistors of the plurality of field effect transistors are identical. Additionally or alternatively, method 100 can, at step 106, configure the plurality of field effect transistors to receive a pulse width modulated control signal that corresponds to a common control signal received by all field effect transistors of the plurality of field effect transistors. Additionally or alternatively, method 100 can, at step 106, configure a pulse width modulation control circuit to supply the pulse width modulated control signal to the plurality of field effect transistors. In some of these implementations, the pulse width modulation control circuit can be configured to cause the pulse width modulated control signal to exhibit a period having a duration less than a characteristic response time of the one or more gated output power networks and a configurable duty cycle. In this context, a response time can be approximately three orders of magnitude greater than a PWM period, a PWM period on the order of nanoseconds for a characteristic response time on the order of microseconds, a response time more than two orders of magnitude greater than a PWM period, etc. In some of these implementations, the device can correspond to one or more semiconductor layers of a semiconductor device. Additionally or alternatively, the one or more semiconductor layers can correspond to one or more die of the semiconductor device. Additionally or alternatively, the pulse width modulation control circuit can be located on the one or more die, on a semiconductor device package including the semiconductor device, and/or off of the semiconductor device package including the semiconductor device. In other implementations, at least one of the one or more semiconductor layers can correspond to a package substrate of a semiconductor device package. Additionally or alternatively, the pulse width modulation control circuit can be located on the package substrate, on the semiconductor device package including the package substrate, or off of the semiconductor device package including the package substrate.

The term “field effect transistor strength,” as used herein, can generally refer to strength of an electric field used by a field effect transistor to control the flow of current in a semiconductor. For example, and without limitation, strength of a FET can correlate with width per length of an electrical channel in the FET in combination with voltage level applied to the FET. In this context, electric field strength of the gate can be a direct result of carrier density in the electrical channel.

The term “common control signal,” as used herein, can generally refer to a control signal that is simultaneously provided to and received by more than one power field effect transistor. For example, and without limitation, a common control signal can correspond to a control signal that is supplied by parallel communication media (e.g., signal lines) to multiple power field effect transistors.

The term “pulse width modulation control circuit,” as used herein, can generally refer to an integrated circuit that creates a PWM signal that serves as a control signal. For example, and without limitation, a PWM circuit can correspond to a PWM controller that is connected to a power supply and that switches a power field effect transistor enable signal line between high (e.g., logical one) and low (e.g., logical zero) at a rate and duty cycle that governs gating applied by the plurality of field effect transistors in order to regulate the gated output power of the one or more gated output power networks. In this context, the PWM control circuit can include or be responsive to logic that controls the duty cycle in response to one or more commands supplied by one or more processors and/or one or more signals supplied by one or more sensors (e.g., temperature sensors, voltage sensors, current sensors, etc.).

Referring to FIG. 2, an example device 200 for power field effect transistor control can be configured according to one or more of the methods disclosed herein with reference to FIG. 1. For example, the device 200 can include one or more input power networks 202, one or more gated output power networks 204, and a plurality of power field effect transistors 206A, 206B, and 206C configured to receive power supplied by the one or more input power networks 202. The plurality of power field effect transistors 206A, 206B, and 206C can also be configured to receive a pulse width modulated control signal S. The plurality of power field effect transistors 206A, 206B, and 206C can further be configured to gate the supplied power from the one or more input power networks 202 in response to the pulse width modulated control signal S and convey the gated power to the one or more gated output power networks 204.

Individual power field effect transistors of the plurality of power field effect transistors 206A, 206B, and 206C can be identical in one or more ways. For example, field effect transistor strengths of all field effect transistors of the plurality of power field effect transistors 206A, 206B, and 206C can be identical. Additionally or alternatively, aging effect of all field effect transistors of the plurality of power field effect transistors 206A, 206B, and 206C can substantially be identical (e.g., nearly identical within a statistical distribution having a small sigma). Additionally or alternatively, all field effect transistors of the plurality of power field effect transistors 206A, 206B, and 206C can be identical in terms of type, manufacturer, model, batch, etc.

PWM control signal S can correspond to a common control signal received by all field effect transistors of the plurality of power field effect transistors 206A, 206B, and 206C. For example, PWM control signal S can serve as an enable signal received by transistor legs of all field effect transistors of the plurality of power field effect transistors 206A, 206B, and 206C. As illustrated at 208, the PWM control signal S can modulate the pulse width over time to ramp power up or down according to a continuous power field effect transistor conductance profile, and its quantization can be limited only by the resolution of the control signal's duty cycle.

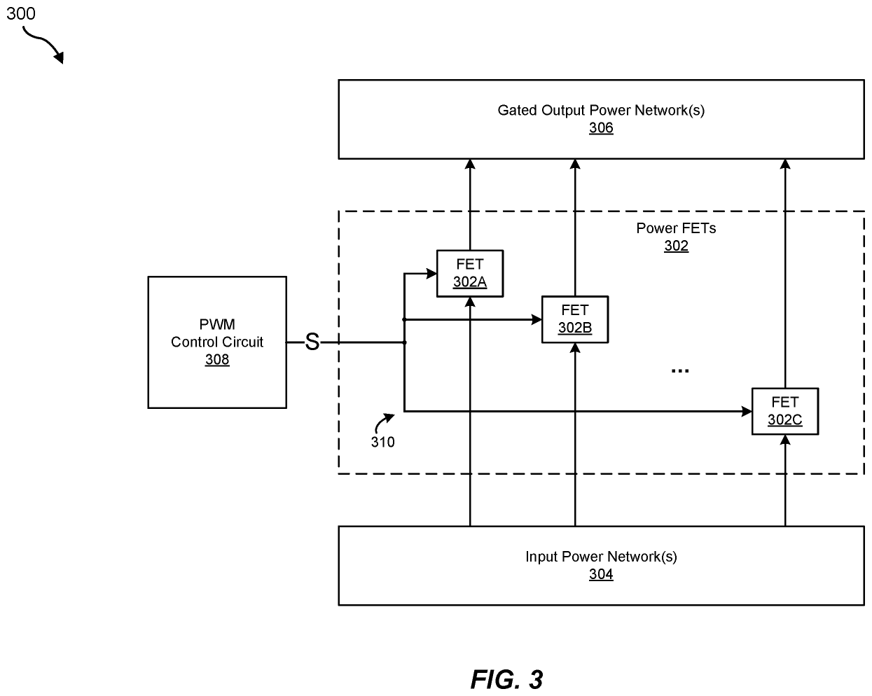

Referring to FIG. 3, an example device 300 for power field effect transistor control can be configured according to one or more of the methods disclosed herein with reference to FIG. 1 and include one or more of the features described above with reference to FIG. 2. For example, device 300 can include a plurality of power field effect transistors 302, such as power field effect transistors 302A, 302B, and 302C. Additionally, device 300 can include one or more input power networks 304 and one or more gated output power networks 306, and the plurality of power field effect transistors 302 can be located on a plurality of power channels (e.g., metal layers, through silicon vias, wires, bumps, etc.) that convey power from the one or more input power networks 304 to the one or more gated output power networks 306. Further, device 300 can include a pulse width modulation control circuit 308 supplying a pulse width modulated control signal S to the plurality of power field effect transistors 302. For example, the pulse width modulation control circuit 308 can be configured to cause the pulse width modulated control signal S to exhibit a period having a duration less than a characteristic response time of the one or more gated output power networks 306 (e.g., a response time approximately three orders of magnitude greater than a PWM period, a PWM period on the order of nanoseconds for a characteristic response time on the order of microseconds, a response time more than two orders of magnitude greater than a PWM period, etc.). Additionally, the pulse width modulation control circuit 308 can be configured to supply the pulse width modulated control signal S to each of the plurality of power field effect transistors 302 via parallel signal lines 310.

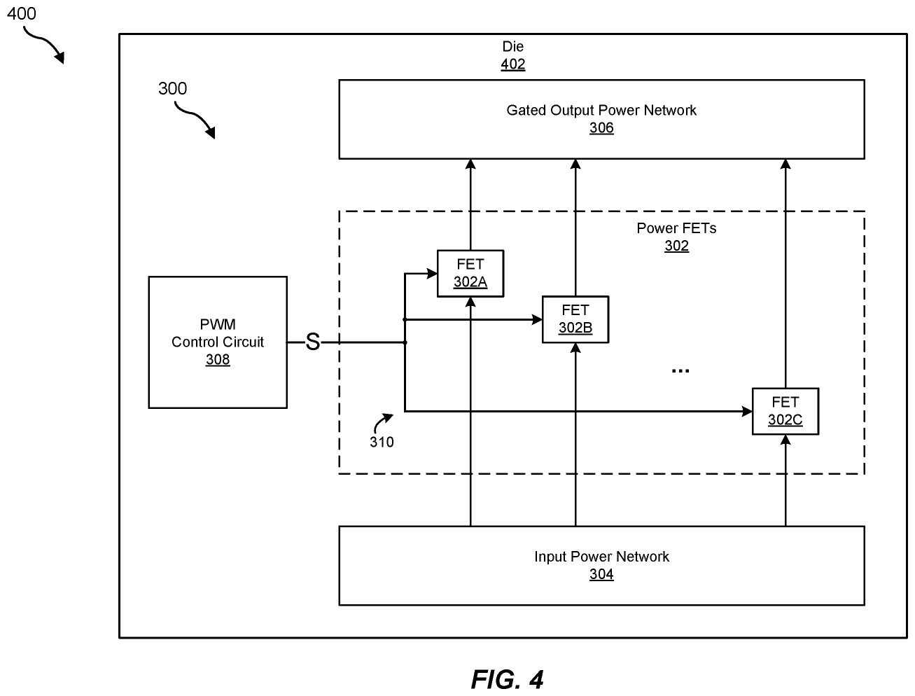

Referring to FIG. 4, an example device 400 can correspond to a semiconductor layer. For example, the semiconductor layer can correspond to a die 402 of a semiconductor device. Additionally, device 400 can include all of the features of the device 300 detailed above with reference to FIG. 3, such as the plurality of power field effect transistors 302, including power field effect transistors 302A, 302B, and 302C, the one or more input power networks 304, the one or more gated output power networks 306, the PWM control circuit 308, and the parallel signal lines 310. Thus, the device 400 can be entirely implemented in a same die 402 of a semiconductor device.

Referring to FIG. 5, an example device 500 can correspond to a semiconductor layer. For example, the semiconductor layer can correspond to a layer of a semiconductor device package 502 (e.g., a package substrate or any other layer of the package) and/or a die 402 of a semiconductor device enclosed by the package 502 and as described above with reference to FIG. 4. Additionally, device 500 can include all of the features of the device 300 detailed above with reference to FIG. 3, such as the plurality of power field effect transistors 302, including power field effect transistors 302A, 302B, and 302C, the input power network 304, the gated output power network 306, the PWM control circuit 308, and the parallel signal lines 310. As shown in FIG. 5, PWM control circuit 308 can be located off of the die 402 but on the semiconductor device package 502. For example, PWM control circuit 308 can be located on a package substrate of the semiconductor device package 502.

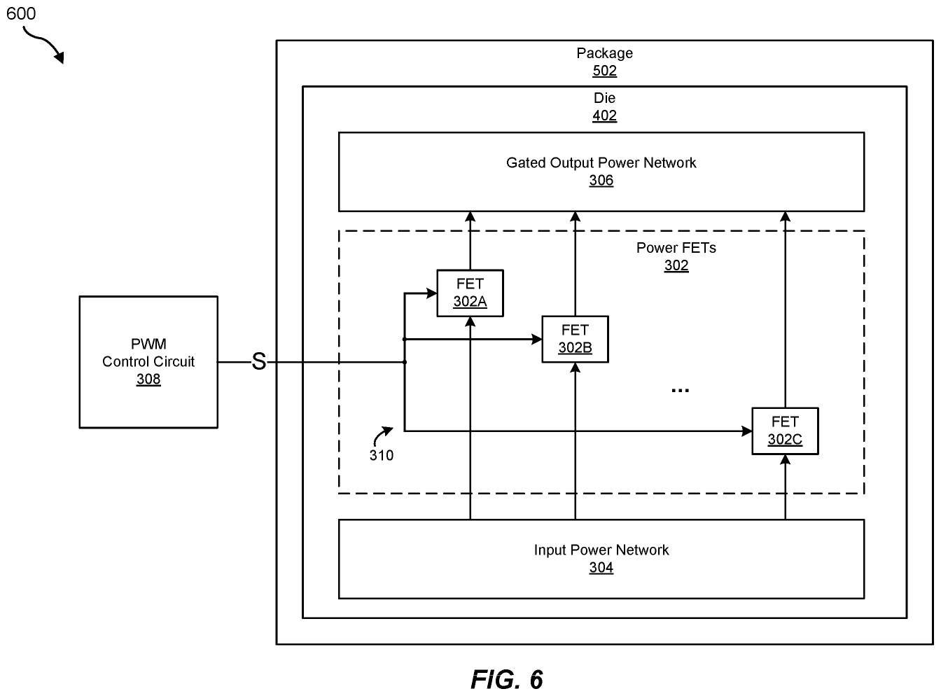

Referring to FIG. 6, an example device 600 can at least partly correspond to a semiconductor layer. For example, the semiconductor layer can correspond to a layer of a semiconductor device package 502 (e.g., a package substrate or any other layer of the package) as described above with reference to FIG. 5. Alternatively or additionally, the semiconductor layer can correspond to a die 402 of a semiconductor device enclosed by the package 502 and as described above with reference to FIG. 4. Additionally, device 600 can include all of the features of the device 300 detailed above with reference to FIG. 3, such as the plurality of power field effect transistors 302, including power field effect transistors 302A, 302B, and 302C, the input power network 304, the gated output power network 306, the PWM control circuit 308, and the parallel signal lines 310. As shown in FIG. 6, PWM control circuit 308 can be located off of the semiconductor device package 502. For example, PWM control circuit 308 can be located on a printed circuit board to which the semiconductor device package 502 is connected.

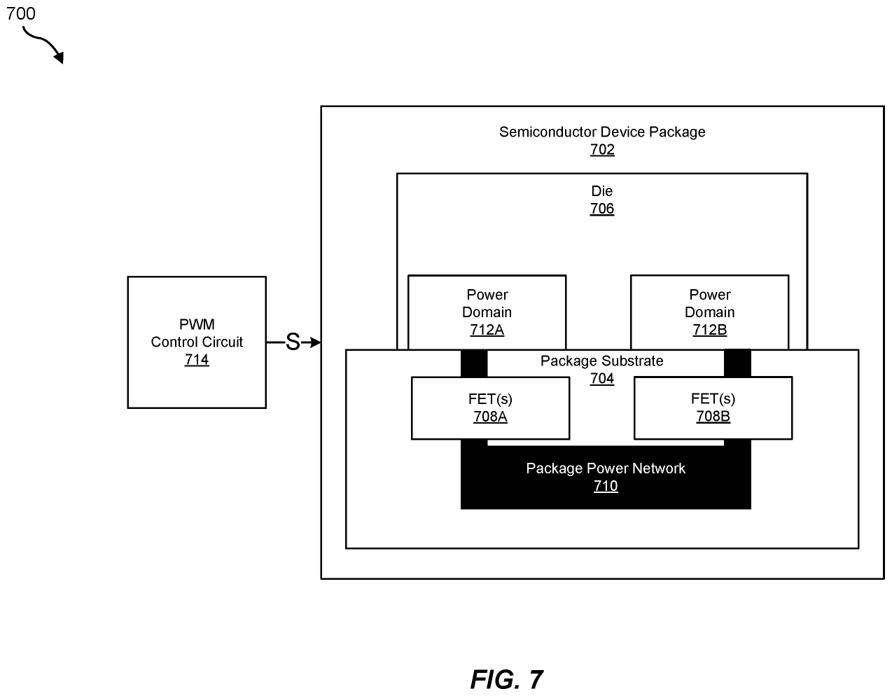

FIGS. 7-13 illustrate example systems 700, 800, 900, 950, 1000, 1100, 1200, and 1300 that implement method 100 of FIG. 1 and/or one or more of devices 200, 300, 400, 500, and 600 of FIGS. 2-6. Example systems 700, 800, 900, 950, 1000, 1100, 1200, and 1300 can respectively include semiconductor device packages 702, 802, 902, 952, 1002, 1102, 1202, and 1302. These packages 702, 802, 902, 952, 1002, 1102, 1202, and 1302 can respectively include package substrates 704, 804, 904, 954, 1004, 1104, 1204, and 1304 and one or more die 706, 806, 906, 956, 1006, 1106, 1206, and 1306 respectively located on the package substrates 704, 804, 904, 954, 1004, 1104, 1204, and 1304. Additionally, packages 702, 802, 902, 952, 1002, 1102, 1202, and 1302 can respectively include pluralities of field effect transistors 708A and 708B, 808A and 808B, 908A and 908B, 958A and 958B, 1008A and 1008B, 1108A and 1108B, 1208A and 1208B, and 1308A and 1308B that are configured to receive power supplied by one or more input power networks of their respective semiconductor device packages 702, 802, 902, 952, 1002, 1102, 1202, and 1302 and a pulse width modulated control signal S. Also, the pluralities of field effect transistors 708A and 708B, 808A and 808B, 908A and 908B, 958A and 958B, 1008A and 1008B, 1108A and 1108B, 1208A and 1208B, and 1308A and 1308B can be configured to gate the supplied power in response to the pulse width modulated control signal S and convey the gated power to one or more gated output power networks of the semiconductor device packages 702, 802, 902, 952, 1002, 1102, 1202, and 1302.

The input power networks of the semiconductor device packages 702, 802, 902, 952, 1002, 1102, 1202, and 1302 can correspond to package power networks 710, 810, 910, 960, 1010, 1110, 1210, and 1310 respectively located in package substrates 704, 804, 904, 954, 1004, 1104, 1204, and 1304. Alternatively or additionally, the input power networks of the semiconductor device packages 702, 802, 902, 952, 1002, 1102, 1202, and 1302 can correspond to one or more metal layers and/or one or more bumps connecting the pluralities of field effect transistors 708A and 708B, 808A and 808B, 908A and 908B, 958A and 958B, 1008A and 1008B, 1108A and 1108B, 1208A and 1208B, and 1308A and 1308B to respective power sources, such as the package power networks 710, 810, 910, 960, 1010, 1110, 1210, and 1310. In some implementations, metal layers included in the input power networks can be located in the package substrates 704, 804, 904, 954, 1004, 1104, 1204, and 1304. Alternatively or additionally, metal layers included in the input power networks can be located in the one or more die 706, 806, 906, 956, 1006, 1106, 1206, and 1306.

The term “power source,” as used herein, can generally refer to a material component of a semiconductor device and/or semiconductor device package that provides electrical connection between a chip and different circuits (e.g., of a printed circuit board). For example, and without limitation, a power source can correspond to a package substrate, an additional die (e.g., an active interposer die, a lower stacked die in a 3D stack, etc.), etc.

The term “additional die,” as used herein, can generally refer to a die in a 3D stack or connected to the 3D stack. For example, and without limitation, an additional die can correspond to an active interposer die, any lower stacked die in a 3D stack, etc. In this context, an active interposer die can correspond to a bottom circuit die in a stacked circuit die configuration. For example, and without limitation, an active interposer die can be used to integrate flexible and distributed interconnect fabrics for scalable chiplet traffic, energy-efficient 3D-plugs using fine pitch interconnects, power management features for power supply closer to the cores, and memory-IO controller and PHY for off-chip communication.

The term “stacking,” as used herein can generally refer to 3D integrated circuit manufacture processes that build one semiconductor layer (e.g., die or wafer) atop another. For example, and without limitation, stacking procedures can include die-to-die stacking, die-to-wafer stacking, and/or wafer-to-wafer stacking. In die-to-die stacking, electronic components are built on multiple die that are then aligned and bonded to one another. In die-to-wafer stacking, electronic components are built on two or more semiconductor wafers; one wafer is diced, and the resulting die are then aligned and bonded onto die sites of the other wafer. In wafer to wafer stacking, electronic components are built on two or more semiconductor wafers that are then aligned, bonded, and diced into 3D integrated circuits. In this context, a “3D stack” and/or “3D stacked die” can correspond to a 3D integrated circuit manufactured according to a 3D stacking process.

The gated output power networks of the semiconductor device packages 702, 802, 902, 952, 1002, 1102, 1202, and 1302 can correspond to one or more metal layers, one or more redistribution layers, and/or one or more through silicon vias connecting the pluralities of field effect transistors 708A and 708B, 808A and 808B, 908A and 908B, 958A and 958B, 1008A and 1008B, 1108A and 1108B, 1208A and 1208B, and 1308A and 1308B to respective loads, such as one or more power domains 712A and 712B, 812A and 812B, 912A and 912B, 962A and 962B, 1012A and 1012B, 1112A and 1112B, 1212A and 1212B, and 1312A and 1312B. The one or more metal layers, one or more redistribution layers, and/or one or more through silicon vias can be located in the package substrates 704, 804, 904, 954, 1004, 1104, 1204, and 1304. Alternatively or additionally, one or more metal layers, one or more redistribution layers, and/or one or more through silicon vias can be located in the one or more die 706, 806, 906, 956, 1006, 1106, 1206, and 1306.

The pluralities of field effect transistors 708A and 708B, 808A and 808B, 908A and 908B, 958A and 958B, 1008A and 1008B, 1108A and 1108B, 1208A and 1208B, and 1308A and 1308B can be implemented in various locations in their respective semiconductor device packages 702, 802, 902, 952, 1002, 1102, 1202, and 1302. For example, the pluralities of field effect transistors 708A and 708B, 808A and 808B, 908A and 908B, 958A and 958B can be located in the package substrates 704, 804, 904, and 954. Additionally, the pluralities of field effect transistors 1008A and 1008B, 1108A and 1108B, 1208A and 1208B, and 1308A and 1308B can be located in the one or more die 1006, 1106, 1206, 1306.

Examples systems 700, 800, 900, 950, 1000, 1100, 1200, and 1300 can include respective PWM control circuits 714, 814, 914, 964, 1014, 1114, 1214, and 1314 that can supply the PWM control signal S. The PWM control circuits 714, 814, 914, 964, 1014, 1114, 1214, and 1314 can be implemented in various locations in their respective examples systems 700, 800, 900, 950, 1000, 1100, 1200, and 1300. For example, PWM control circuits 714 and 1014 can be located off of their respective semiconductor device packages 702 and 1002. Additionally, PWM control circuits 814 and 1114 can be located on their respective semiconductor device packages 802 and 1102, but not on the respective package substrates 804 and 1104 thereof nor on the respective die 806 and 1106 thereof. Also, PWM control circuits 914 and 1214 can be located on their respective package substrates 904 and 1204. Further, PWM control circuits 964 and 1314 can be located on their respective one or more die 956 and 1306.

Referring to FIG. 7, PWM control circuit 714 can be located off of the semiconductor device package 702 and supply the PWM control signal S to the semiconductor device package 702. For example, PWM control circuit 714 can supply a common PWM control signal S to a plurality of field effect transistors 708A and 708B located in the package substrate 704 by parallel signal lines that can be located in the semiconductor device package 702, the package substrate 704, and/or the one or more die 706. Field effect transistor strengths of all field effect transistors of the plurality of field effect transistors 708A and 708B can be identical, and the PWM control circuit 714 can be configured to cause the PWM control signal S to exhibit a period having a duration less than a characteristic response time of one or more gated output power networks that can be located in the package substrate 704 and/or the one or more die 706. In this context, a response time can be approximately three orders of magnitude greater than a PWM period, a PWM period on the order of nanoseconds for a characteristic response time on the order of microseconds, a response time more than two orders of magnitude greater than a PWM period, etc.

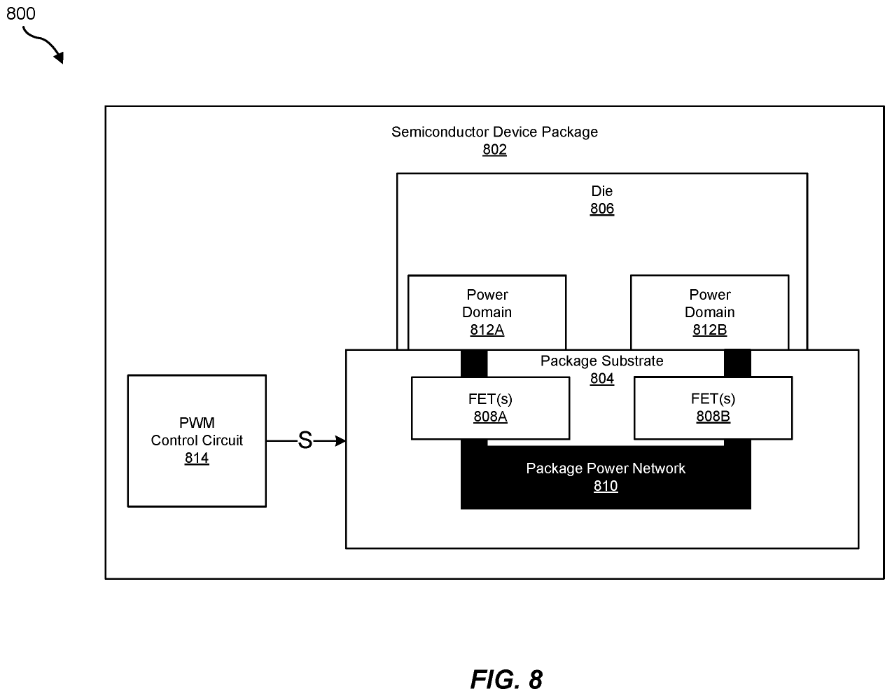

Referring to FIG. 8, PWM control circuit 814 can be located on the semiconductor device package 802 and supply the PWM control signal S to the semiconductor device package 802. For example, PWM control circuit 814 can supply a common PWM control signal S to a plurality of field effect transistors 808A and 808B located in the package substrate 804 by parallel signal lines that can be located in the semiconductor device package 802, the package substrate 804, and/or the one or more die 806. Field effect transistor strengths of all field effect transistors of the plurality of field effect transistors 808A and 808B can be identical, and the PWM control circuit 814 can be configured to cause the PWM control signal S to exhibit a period having a duration less than a characteristic response time of one or more gated output power networks that can be located in the package substrate 804 and/or the one or more die 806. In this context, a response time can be approximately three orders of magnitude greater than a PWM period, a PWM period on the order of nanoseconds for a characteristic response time on the order of microseconds, a response time more than two orders of magnitude greater than a PWM period, etc.

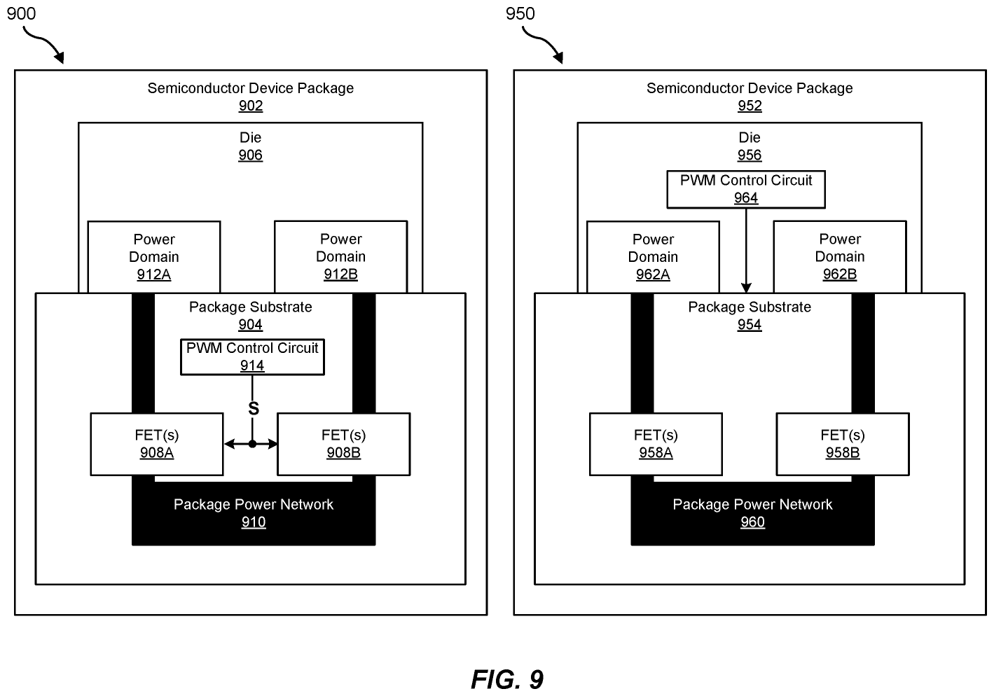

Referring to FIG. 9, PWM control circuit 914 can be located on the package substrate 904 and supply the PWM control signal S to the plurality of field effect transistors 908A and 908B located in the package substrate 904. For example, PWM control circuit 914 can supply a common PWM control signal S to the plurality of field effect transistors 908A and 908B by parallel signal lines that can be located in the package substrate 904. Field effect transistor strengths of all field effect transistors of the plurality of field effect transistors 908A and 908B can be identical, and the PWM control circuit 914 can be configured to cause the PWM control signal S to exhibit a period having a duration less than a characteristic response time of one or more gated output power networks that can be located in the package substrate 904 and/or the one or more die 906. In this context, a response time can be approximately three orders of magnitude greater than a PWM period, a PWM period on the order of nanoseconds for a characteristic response time on the order of microseconds, a response time more than two orders of magnitude greater than a PWM period, etc.

As also shown in FIG. 9, PWM control circuit 964 can be located on the one or more die 956 and supply the PWM control signal S to the plurality of field effect transistors 958A and 958B located in the package substrate 954. For example, PWM control circuit 964 can supply a common PWM control signal S to the plurality of field effect transistors 958A and 958B by parallel signal lines that can be located in the package substrate 954. Field effect transistor strengths of all field effect transistors of the plurality of field effect transistors 958A and 958B can be identical, and the PWM control circuit 964 can be configured to cause the PWM control signal S to exhibit a period having a duration less than a characteristic response time of one or more gated output power networks that can be located in the package substrate 954 and/or the one or more die 956. In this context, a response time can be approximately three orders of magnitude greater than a PWM period, a PWM period on the order of nanoseconds for a characteristic response time on the order of microseconds, a response time more than two orders of magnitude greater than a PWM period, etc.

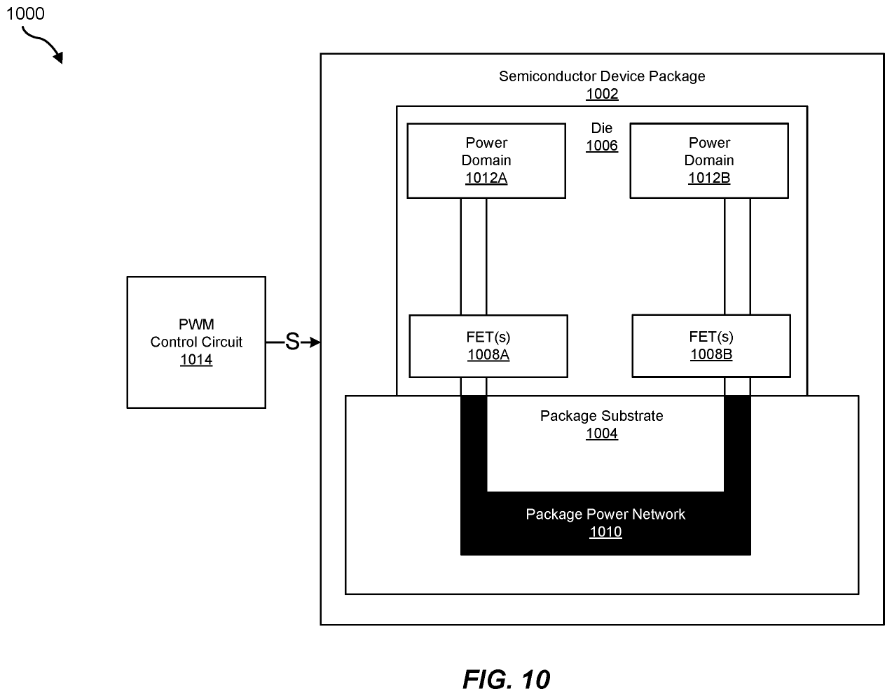

Referring to FIG. 10, PWM control circuit 1014 can be located off of the semiconductor device package 1002 and supply the PWM control signal S to the semiconductor device package 1002. For example, PWM control circuit 1014 can supply a common PWM control signal S to a plurality of field effect transistors 1008A and 1008B located in the one or more die 1006 by parallel signal lines that can be located in the semiconductor device package 1002, the package substrate 1004, and/or the one or more die 1006. Field effect transistor strengths of all field effect transistors of the plurality of field effect transistors 1008A and 1008B can be identical, and the PWM control circuit 1014 can be configured to cause the PWM control signal S to exhibit a period having a duration less than a characteristic response time of one or more gated output power networks that can be located in the one or more die 1006. In this context, a response time can be approximately three orders of magnitude greater than a PWM period, a PWM period on the order of nanoseconds for a characteristic response time on the order of microseconds, a response time more than two orders of magnitude greater than a PWM period, etc.

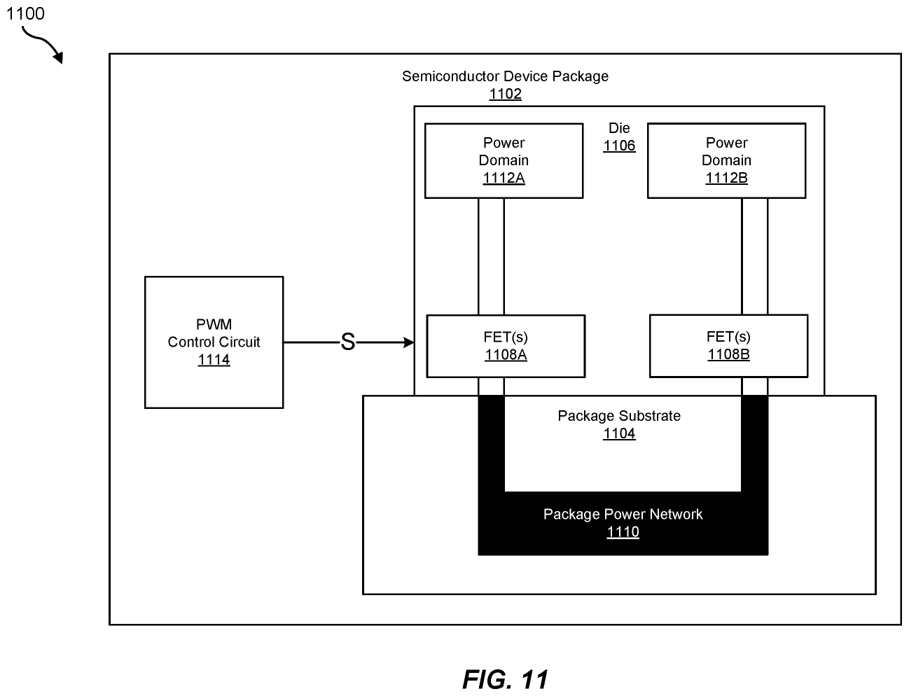

Referring to FIG. 11, PWM control circuit 1014 can be located on the semiconductor device package 1102 and supply the PWM control signal S to the semiconductor device package 1102. For example, PWM control circuit 1114 can supply a common PWM control signal S to a plurality of field effect transistors 1108A and 1108B located in the one or more die 1106 by parallel signal lines that can be located in the semiconductor device package 1102, the package substrate 1104, and/or the one or more die 1106. Field effect transistor strengths of all field effect transistors of the plurality of field effect transistors 1108A and 1108B can be identical, and the PWM control circuit 1114 can be configured to cause the PWM control signal S to exhibit a period having a duration less than a characteristic response time of one or more gated output power networks that can be located in the one or more die 1106. In this context, a response time can be approximately three orders of magnitude greater than a PWM period, a PWM period on the order of nanoseconds for a characteristic response time on the order of microseconds, a response time more than two orders of magnitude greater than a PWM period, etc.

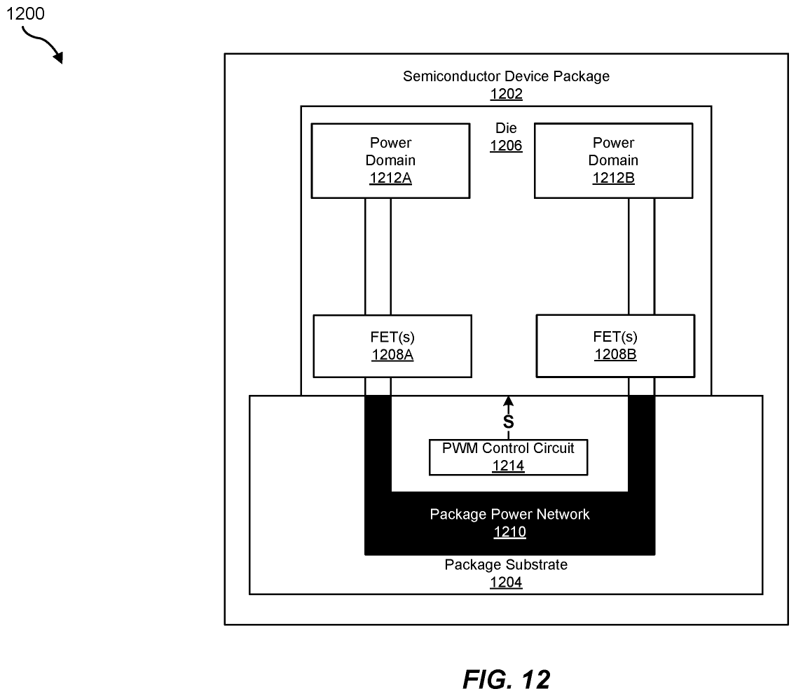

Referring to FIG. 12, PWM control circuit 1214 can be located on the package substrate 1204 and supply the PWM control signal S to the plurality of field effect transistors 1208A and 1208B located in the one or more die 1206. For example, PWM control circuit 1214 can supply a common PWM control signal S to the plurality of field effect transistors 1208A and 1208B by parallel signal lines that can be located in the package substrate 1204. Field effect transistor strengths of all field effect transistors of the plurality of field effect transistors 1208A and 1208B can be identical, and the PWM control circuit 1214 can be configured to cause the PWM control signal S to exhibit a period having a duration less than a characteristic response time of one or more gated output power networks that can be located in the one or more die 1206. In this context, a response time can be approximately three orders of magnitude greater than a PWM period, a PWM period on the order of nanoseconds for a characteristic response time on the order of microseconds, a response time more than two orders of magnitude greater than a PWM period, etc.

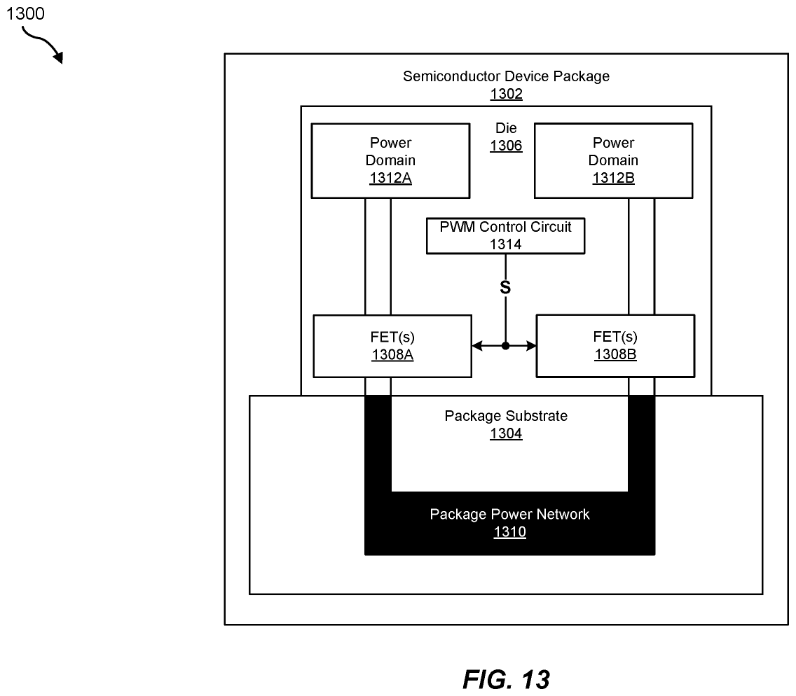

Referring to FIG. 13, PWM control circuit 1314 can be located on the one or more die 1306 and supply the PWM control signal S to the plurality of field effect transistors 1308A and 1308B located in the package substrate 1304. For example, PWM control circuit 1314 can supply a common PWM control signal S to the plurality of field effect transistors 1308A and 1308B by parallel signal lines that can be located in the one or more die 1306. Field effect transistor strengths of all field effect transistors of the plurality of field effect transistors 1308A and 1308B can be identical, and the PWM control circuit 1314 can be configured to cause the PWM control signal S to exhibit a period having a duration less than a characteristic response time of one or more gated output power networks that can be located in the one or more die 1306. In this context, a response time can be approximately three orders of magnitude greater than a PWM period, a PWM period on the order of nanoseconds for a characteristic response time on the order of microseconds, a response time more than two orders of magnitude greater than a PWM period, etc.

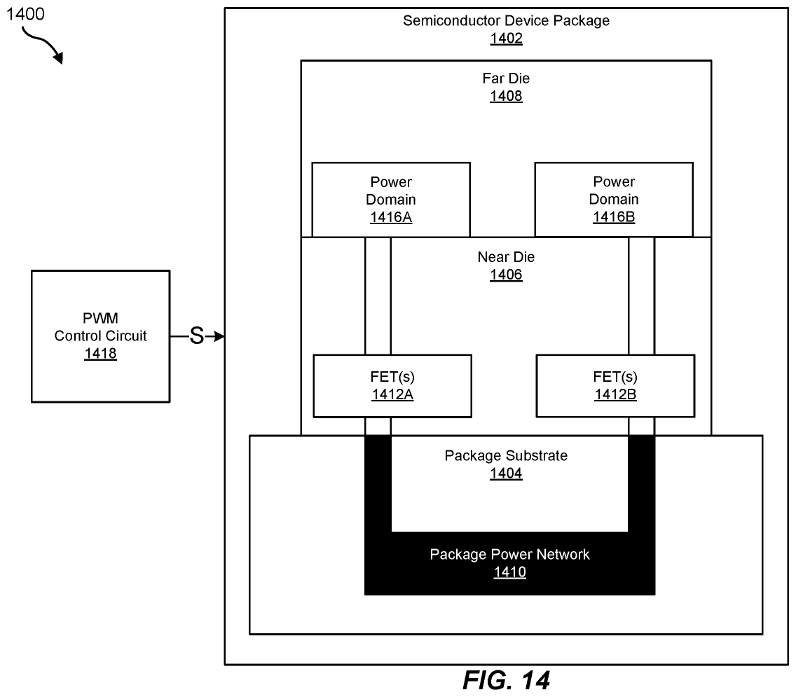

FIGS. 14-18 illustrate example systems 1400, 1500, 1600, 1700, and 1800 that implement method 100 of FIG. 1 and/or one or more of devices 200, 300, 400, 500, and 600 of FIGS. 2-6. Example systems 1400, 1500, 1600, 1700, and 1800 can respectively include semiconductor device packages 1402, 1502, 1602, 1702, and 1802. These packages 1402, 1502, 1602, 1702, and 1802 can respectively include package substrates 1404, 1504, 1604, 1704, and 1804, and one or more 3D stacked die respectively located on the package substrates 1404, 1504, 1604, 1704, and 1804. For example, the 3D stacked die can respectively include near die 1406, 1506, 1606, 1706 and 1806 and far die 1408, 1508, 1608, 1708, and 1808, with the near die 1406, 1506, 1606, 1706 and 1806 being located respectively on the package substrate 1404, 1504, 1604, 1704, and 1804 and the far die 1408, 1508, 1608, 1708, and 1808 being stacked respectively atop the near die 1406, 1506, 1606, 1706, and 1806.

Semiconductor device packages 1402, 1502, 1602, 1702, and 1802 can respectively include pluralities of field effect transistors 1412A and 1412B, 1512A and 1512B, 1612A and 1612B, 1712A and 1712B, and 1812A and 1812B that are configured to receive power supplied by one or more input power networks of their respective semiconductor device packages 1402, 1502, 1602, 1702, and 1802 and a pulse width modulated control signal S. Also, the pluralities of field effect transistors 1412A and 1412B, 1512A and 1512B, 1612A and 1612B, 1712A and 1712B, and 1812A and 1812B can be configured to gate the supplied power in response to the pulse width modulated control signal S and convey the gated power to one or more gated output power networks of the semiconductor device packages 1402, 1502, 1602, 1702, and 1802.

The input power networks of the semiconductor device packages 1402, 1502, 1602, 1702, and 1802 can correspond to package power networks 1410, 1510, 1610, 1710, and 1810 respectively located in package substrates 1404, 1504, 1604, 1704, and 1804. Alternatively or additionally, the input power networks of the semiconductor device packages 1402, 1502, 1602, 1702, and 1802 can correspond to one or more metal layers and/or one or more bumps connecting the pluralities of field effect transistors 1412A and 1412B, 1512A and 1512B, 1612A and 1612B, 1712A and 1712B, and 1812A and 1812B to respective power sources, such as the package power networks 1410, 1510, 1610, 1710, and 1810. In some implementations, metal layers included in the input power networks can be located in the package substrates 1404, 1504, 1604, 1704, and 1804. Alternatively or additionally, metal layers included in the input power networks can be located in the 3D stacked die, such as near die 1406, 1506, 1606, 1706 and 1806.

The gated output power networks of the semiconductor device packages 1402, 1502, 1602, 1702, and 1802 can correspond to one or more metal layers, one or more redistribution layers, and/or one or more through silicon vias connecting the pluralities of field effect transistors 1412A and 1412B, 1512A and 1512B, 1612A and 1612B, 1712A and 1712B, and 1812A and 1812B to respective loads, such as one or more power domains 1416A and 1416B, 1516A and 1516B, 1616A and 1616B, 1716A and 1716B, and 1816A and 1816B. The one or more metal layers, one or more redistribution layers, and/or one or more through silicon vias can be located in the 3D stacked die, such as near die 1406, 1506, 1606, 1706 and 1806 and/or far die 1408, 1508, 1608, 1708, and 1808.

The pluralities of field effect transistors 1412A and 1412B, 1512A and 1512B, 1612A and 1612B, 1712A and 1712B, and 1812A and 1812B can be located in the one or more 3D stacked die. For example, die 1006, 1106, 1206, 1306. The pluralities of field effect transistors 1412A and 1412B, 1512A and 1512B, 1612A and 1612B, 1712A and 1712B, and 1812A and 1812B can be located in their respective near die 1406, 1506, 1606, 1706 and 1806.

Examples systems 1400, 1500, 1600, 1700, and 1800 can include respective PWM control circuits 1418, 1518, 1618, 1718, and 1818 that can supply the PWM control signal S. The PWM control circuits 1418, 1518, 1618, 1718, and 1818 can be implemented in various locations in their respective examples systems 1400, 1500, 1600, 1700, and 1800. For example, PWM control circuit 1418 can be located off of its respective semiconductor device packages 1402. Additionally, PWM control circuit 1518 can be located on its respective semiconductor device package 1502, but not on its respective package substrate 1504 nor on its respective 3D stacked die, such as near die 1506 and far die 1508. Also, PWM control circuit 1618 can be located on its respective package substrate 1604. Further, PWM control circuit 1718 can be located on its respective far die 1708, and PWM control circuit 1818 can be located on its respective near die 1806.

Referring to FIG. 14, PWM control circuit 1418 can be located off of the semiconductor device package 1402 and supply the PWM control signal S to the semiconductor device package 1402. For example, PWM control circuit 1418 can supply a common PWM control signal S to a plurality of field effect transistors 1412A and 1412B located in the near die 1406 by parallel signal lines that can be located in the semiconductor device package 1402, the package substrate 1404, the near die 1406, and/or the far die 1408. Field effect transistor strengths of all field effect transistors of the plurality of field effect transistors 1412A and 1412B can be identical, and the PWM control circuit 1418 can be configured to cause the PWM control signal S to exhibit a period having a duration less than a characteristic response time of one or more gated output power networks that can be located in the near die 1406 and/or the far die 1408. In this context, a response time can be approximately three orders of magnitude greater than a PWM period, a PWM period on the order of nanoseconds for a characteristic response time on the order of microseconds, a response time more than two orders of magnitude greater than a PWM period, etc.

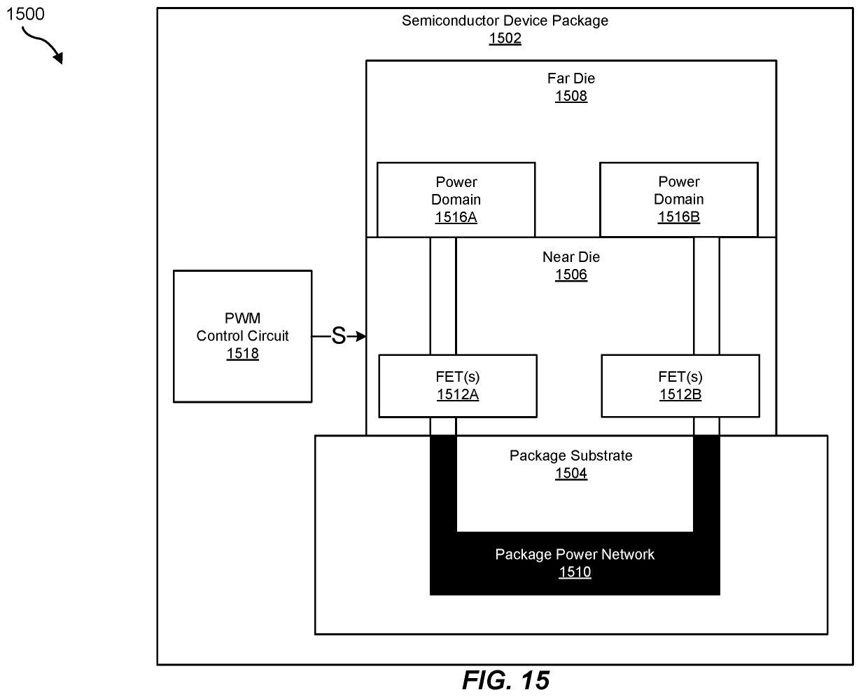

Referring to FIG. 15, PWM control circuit 1518 can be located on the semiconductor device package 1502 and supply the PWM control signal S to the semiconductor device package 1502. For example, PWM control circuit 1518 can supply a common PWM control signal S to a plurality of field effect transistors 1512A and 1512B located in the near die 1506 by parallel signal lines that can be located in the semiconductor device package 1502, the package substrate 1504, the near die 1506, and/or the far die 1508. Field effect transistor strengths of all field effect transistors of the plurality of field effect transistors 1512A and 1512B can be identical, and the PWM control circuit 1518 can be configured to cause the PWM control signal S to exhibit a period having a duration less than a characteristic response time of one or more gated output power networks that can be located in the near die 1506 and/or the far die 1508. In this context, a response time can be approximately three orders of magnitude greater than a PWM period, a PWM period on the order of nanoseconds for a characteristic response time on the order of microseconds, a response time more than two orders of magnitude greater than a PWM period, etc.

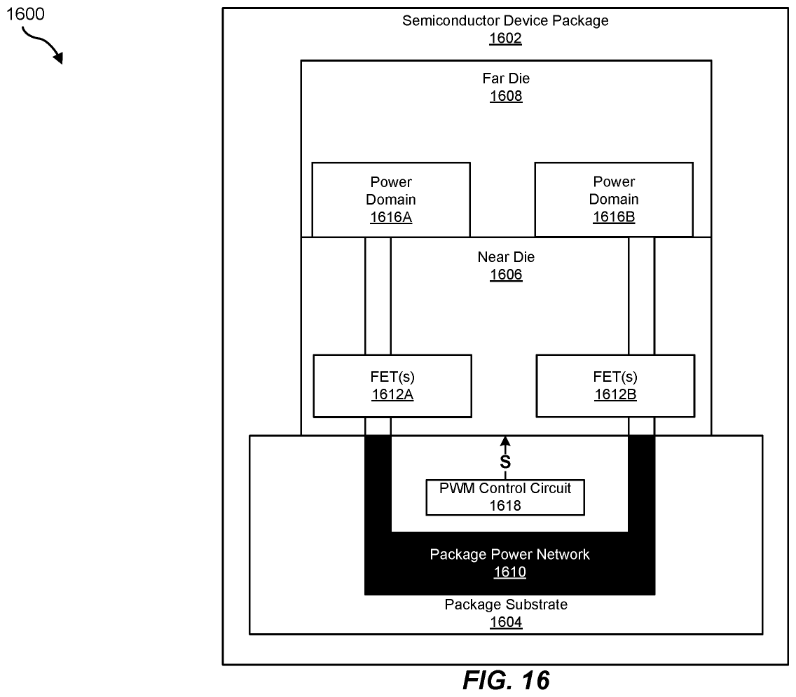

Referring to FIG. 16, PWM control circuit 1618 can be located on the package substrate 1604 and supply the PWM control signal S to the semiconductor device package 1602. For example, PWM control circuit 1618 can supply a common PWM control signal S to a plurality of field effect transistors 1612A and 1612B located in the near die 1606 by parallel signal lines that can be located in the package substrate 1604 and/or the near die 1606. Field effect transistor strengths of all field effect transistors of the plurality of field effect transistors 1612A and 1612B can be identical, and the PWM control circuit 1618 can be configured to cause the PWM control signal S to exhibit a period having a duration less than a characteristic response time of one or more gated output power networks that can be located in the near die 1606 and/or the far die 1608. In this context, a response time can be approximately three orders of magnitude greater than a PWM period, a PWM period on the order of nanoseconds for a characteristic response time on the order of microseconds, a response time more than two orders of magnitude greater than a PWM period, etc.

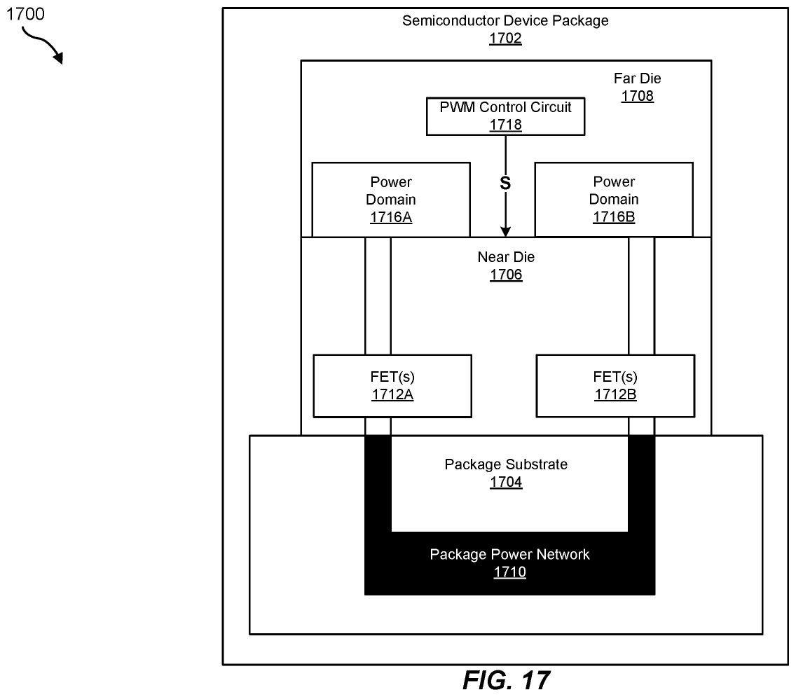

Referring to FIG. 17, PWM control circuit 1718 can be located on the far die 1708 and supply the PWM control signal S to the semiconductor device package 1702. For example, PWM control circuit 1718 can supply a common PWM control signal S to a plurality of field effect transistors 1712A and 1712B located in the near die 1706 by parallel signal lines that can be located in the near die 1706 and/or the far die 1708. Field effect transistor strengths of all field effect transistors of the plurality of field effect transistors 1712A and 1712B can be identical, and the PWM control circuit 1718 can be configured to cause the PWM control signal S to exhibit a period having a duration less than a characteristic response time of one or more gated output power networks that can be located in the near die 1706 and/or the far die 1708. In this context, a response time can be approximately three orders of magnitude greater than a PWM period, a PWM period on the order of nanoseconds for a characteristic response time on the order of microseconds, a response time more than two orders of magnitude greater than a PWM period, etc.

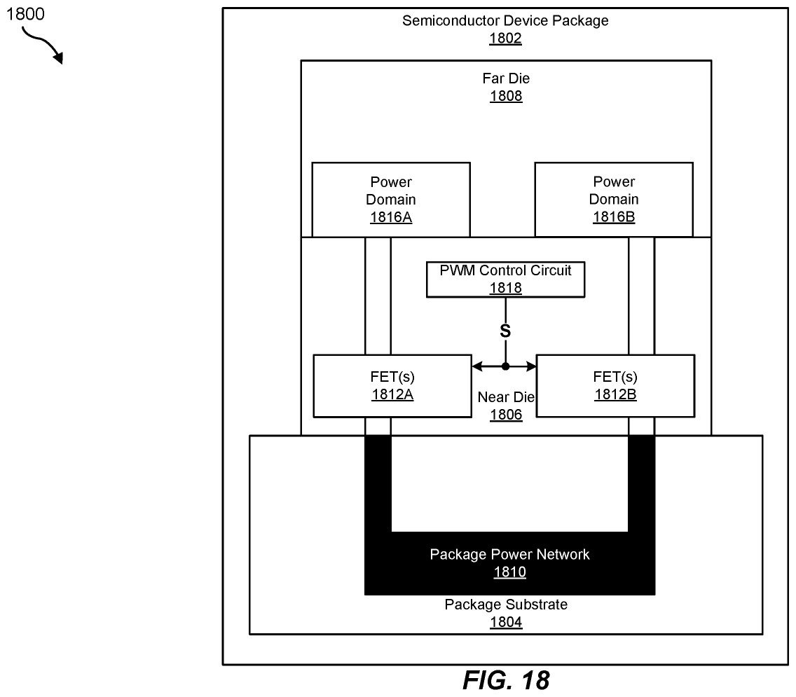

Referring to FIG. 18, PWM control circuit 1818 can be located on the near die 1806 and supply the PWM control signal S to the semiconductor device package 1802. For example, PWM control circuit 1818 can supply a common PWM control signal S to a plurality of field effect transistors 1812A and 1812B located in the near die 1806 by parallel signal lines that can be located in the near die 1806. Field effect transistor strengths of all field effect transistors of the plurality of field effect transistors 1812A and 1812B can be identical, and the PWM control circuit 1818 can be configured to cause the PWM control signal S to exhibit a period having a duration less than a characteristic response time of one or more gated output power networks that can be located in the near die 1806 and/or the far die 1808. In this context, a response time can be approximately three orders of magnitude greater than a PWM period, a PWM period on the order of nanoseconds for a characteristic response time on the order of microseconds, a response time more than two orders of magnitude greater than a PWM period, etc.

As set forth above, the disclosed systems and methods can accomplish power field effect transistor control. For example, by configuring one or more input power networks to supply power to a plurality of field effect transistors, configuring one or more gated output power networks to receive gated power from the plurality of field effect transistors, and configuring the plurality of field effect transistors to receive a pulse width modulated control signal and to gate the supplied power in response to the pulse width modulated control signal, numerous benefits can be achieved.

Benefits achieved by the disclosed systems and methods can arise, at least in part, by avoiding breaking up field effect transistors into different strength FETS and/or using multiple control lines to control different groups of field effect transistors to achieve different conductances. Instead, the disclosed systems and methods can ramp power supplies through power field effect transistor FETs and use a Pulse-Width-Modulation (PWM) scheme to control all power field effect transistors with a common control signal. Such implementations of the disclosed systems and methods can simplify the control of field effect transistor conductance by avoiding use of different control lines to different field effect transistor macros and reducing the number of signals needed for control to one. Such implementations can also simplify field effect transistor macro design because only one type of macro is needed with only a single field effect transistor macro FET strength required. This benefit can arise when the overall field effect transistor conductance is modulated by the PWM pulse duty-cycle, instead of by enabling different amounts of field effect transistor macros or different strength FETs inside the field effect transistor macros. Additionally, since all of the FETs can be identical (e.g., in terms of field effect transistor strength and aging effect) and can be turned on and off simultaneously, even wear-leveling can be achieved.

Certain implementations of the disclosed systems and methods can achieve conductance changes through PWM shaping of the common control signal, instead of by quantizing FET strengths inside the power field effect transistor macros and/or utilizing more complex, multi-bit control schemes. Thus, these implementations can aid FET overheating/degradation prevention by providing periodic off-time to allow the FETs to recover from thermal and current-flow stresses as the gated supply value is ramped up or down. Additionally or alternatively, by using a sufficiently short PWM control signal period, implementations of the disclosed systems and methods can achieve improved voltage ramp profile control, provided that the characteristic response time of the gated supply network (e.g., gated output power network) is significantly longer than the PWM period. In this context, a response time can be approximately three orders of magnitude greater than a PWM period, a PWM period on the order of nanoseconds for a characteristic response time on the order of microseconds, a response time more than two orders of magnitude greater than a PWM period, etc. Further, these implementations can also use one control signal for all field effect transistor macros, thus causing all FETs of all field effect transistor macros to experience the same stress profile over time, which can achieve a uniform wear/degradation profile across all power field effect transistor FETs as time-in-use accumulates. Some of these implementations can increase (e.g., maximize) service life of the power field effect transistors by progressively modulating the effective field effect transistor conductance over time in order to achieve improved voltage ramp profile control and avoid overheating of field effect transistor FETs, thus resulting in even degradation/wear across all the field effect transistor FETs. Finally, the power field effect transistor conductance profile can be continuous, and its quantization can be limited only by the resolution of the control signal's duty cycle.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A device comprising:
one or more input power networks;
one or more gated output power networks; and
a plurality of field effect transistors configured to receive power supplied by the one or more input power networks and a pulse width modulated control signal, wherein the plurality of field effect transistors is configured to gate the supplied power in response to the pulse width modulated control signal and convey the gated power to the one or more gated output power networks.

2. The device of claim 1, wherein field effect transistor strengths of all field effect transistors of the plurality of field effect transistors are identical.

3. The device of claim 1, wherein the pulse width modulated control signal corresponds to a common control signal received by all field effect transistors of the plurality of field effect transistors.

4. The device of claim 1, further comprising a pulse width modulation control circuit supplying the pulse width modulated control signal to the plurality of field effect transistors, wherein the pulse width modulation control circuit is configured to cause the pulse width modulated control signal to exhibit a period having a duration less than a characteristic response time of the one or more gated output power networks and a configurable duty cycle.

5. The device of claim 4, wherein the device corresponds to one or more semiconductor layers of a semiconductor device.

6. The device of claim 5, wherein the one or more semiconductor layers correspond to one or more die of the semiconductor device.

7. The device of claim 6, wherein the pulse width modulation control circuit is located at least one of:
on the one or more die;
on a semiconductor device package including the semiconductor device; or
off of the semiconductor device package including the semiconductor device.

8. The device of claim 5, wherein at least one of the one or more semiconductor layers corresponds to a package substrate of a semiconductor device package.

9. The device of claim 8, wherein the pulse width modulation control circuit is located at least one of:
on the package substrate;
on the semiconductor device package including the package substrate; or
off of the semiconductor device package including the package substrate.

10. A semiconductor device package comprising:
a package substrate;
one or more die located on the package substrate; and
a plurality of field effect transistors configured to receive power supplied by one or more input power networks of the semiconductor device package and a pulse width modulated control signal, wherein the plurality of field effect transistors is configured to gate the supplied power in response to the pulse width modulated control signal and convey the gated power to one or more gated output power networks of the semiconductor device package.

11. The semiconductor device package of claim 10, wherein the plurality of field effect transistors is located in at least one of:
the package substrate; or
the one or more die.

12. The semiconductor device package of claim 10, wherein field effect transistor strengths of all field effect transistors of the plurality of field effect transistors are identical.

13. The semiconductor device package of claim 10, wherein the pulse width modulated control signal corresponds to a common control signal received by all field effect transistors of the plurality of field effect transistors.

14. The semiconductor device package of claim 10, further comprising a pulse width modulation control circuit supplying the pulse width modulated control signal to the plurality of field effect transistors.

15. The semiconductor device package of claim 14, wherein the pulse width modulation control circuit is configured to cause the pulse width modulated control signal to exhibit a period having a duration less than a characteristic response time of the one or more gated output power networks and a configurable duty cycle.

16. The semiconductor device package of claim 14, wherein the pulse width modulation control circuit is located at least one of:
on the one or more die;
on the package substrate;
on the semiconductor device package including the package substrate; or
off of the semiconductor device package including the package substrate.

17. A method comprising:
configuring one or more input power networks to supply power to a plurality of field effect transistors;
configuring one or more gated output power networks to receive gated power from the plurality of field effect transistors; and
configuring the plurality of field effect transistors to receive a pulse width modulated control signal and to gate the supplied power in response to the pulse width modulated control signal.

18. The method of claim 17, wherein field effect transistor strengths of all field effect transistors of the plurality of field effect transistors are identical.

19. The method of claim 17, wherein the pulse width modulated control signal corresponds to a common control signal received by all field effect transistors of the plurality of field effect transistors.

20. The method of claim 17, further comprising:
configuring a pulse width modulation control circuit to supply the pulse width modulated control signal to the plurality of field effect transistors, wherein the pulse width modulation control circuit is configured to cause the pulse width modulated control signal to exhibit a period having a duration less than a characteristic response time of the one or more gated output power networks and a configurable duty cycle.
